(19) United States
(12) Patent Application Publication
(10) Pub. No.: US 2026/0026219 A1
(43) Pub. Date: Jan. 22, 2026

(54) DISPLAY DEVICE AND METHOD FOR FABRICATING THE SAME

(71) Applicant: SAMSUNG DISPLAY CO., LTD., YONGIN-SI (KR)

(72) Inventors: Yun Jong YEO, Yongin-si (KR); Jong Jun BAEK, Yongin-si (KR); Kyong Chol LEE, Yongin-si (KR); Hyun Min CHO, Yongin-si (KR)

(21) Appl. No.: 19/087,680

(22) Filed: Mar. 24, 2025

(30) Foreign Application Priority Data
Jul. 17, 2024 (KR) 10-2024-0094654
Dec. 12, 2024 (KR) 10-2024-0184592

(51) Int. Cl. H10K 59/131; G02B 27/01; H10H 29/01; H10H 29/49; H10K 59/12

(52) U.S. Cl. CPC H10K 59/131; G02B 27/0172; H10H 29/012; H10H 29/49; H10K 59/1201; G02B 2027/0178

(57) ABSTRACT

A display device includes a substrate having a transistor disposed thereon. A gate insulator is disposed on the transistor. A plurality of conductive layers is disposed on the gate insulator. The plurality of conductive layers is spaced apart from one another. An interlayer dielectric layer is disposed on the plurality of conductive layers. The interlayer dielectric layer comprises an inorganic material. A planarization layer is disposed on the interlayer dielectric layer and defines an opening. The opening exposes the interlayer dielectric layer. The planarization layer comprises an inorganic material. 1

This application claims priority under 35 U.S.C. § 119 to Korean Patent Application No. 10-2024-0094654, filed on Jul. 17, 2024 in the Korean Intellectual Property Office (KIPO) and Korean Patent Application No. 10-2024-0184592, filed on Dec. 12, 2024 in KIPO, the disclosures of which are incorporated by reference in their entireties herein.

### TECHNICAL FIELD

The present disclosure relates to a display device and a method for fabricating the same.

### DISCUSSION OF RELATED ART

The demands for display devices are increasing along with the advancement of the information-oriented society. For example, display devices are being applied into an increasing variety of electronic devices, such as smart phones, digital cameras, laptop computers, navigation devices and smart televisions. Display devices may be flat panel display devices such as a liquid-crystal display device, a field emission display device and an organic light-emitting display device. Among such flat panel display devices, a light-emitting display device includes a light-emitting element that is self emissive, so that each of the pixels of the display panel can emit light by themselves without the need for a backlight unit that supplies light to the display panel.

### SUMMARY

Aspects of the present disclosure provide a display device that can provide high-resolution images and a method for fabricating a display device.

Aspects of the present disclosure also provide a method for increasing the reliability of display devices.

It should be noted that objects of the present disclosure are not limited to the above-mentioned objects; and other objects of the present disclosure will be apparent to those skilled in the art from the following descriptions.

The details of one or more embodiments of the subject matter described in this specification are set forth in the accompanying drawings and the description below.

According to an embodiment of the present disclosure, a display device includes a substrate having a transistor disposed thereon. A gate insulator is disposed on the transistor. A plurality of conductive layers is disposed on the gate insulator. The plurality of conductive layers is spaced apart from one another. An interlayer dielectric layer is disposed on the plurality of conductive layers. The interlayer dielectric layer comprises an inorganic material. A planarization layer is disposed on the interlayer dielectric layer and defines an opening. The opening exposes the interlayer dielectric layer. The planarization layer comprises an inorganic material.

In some embodiments, each of the plurality of conductive layers may overlap the opening of the planarization layer.

In some embodiments, the planarization layer may be disposed between adjacent conductive layers of the plurality of conductive layers in a plan view.

In some embodiments, the plurality of conductive layers may comprise a conductive metal, and the conductive layers are disposed on a same layer as each other and overlap each other in a direction parallel to an upper surface of the substrate.

In some embodiments, the plurality of conductive layers may have an island-like shape.

In some embodiments, the interlayer dielectric layer may be disposed on an entirety of the substrate. The interlayer dielectric layer may be in direct contact with an entirety of an upper surface and lateral side surfaces of the plurality of conductive layers to cover the plurality of conductive layers.

In some embodiments, the interlayer dielectric layer may have a height difference between portions that do not overlap with the opening and portions that overlap with the opening.

In some embodiments, a thickness of the planarization layer may be in a range from about 50% to about 150% of the height difference of the interlayer dielectric layer.

In some embodiments, the interlayer dielectric layer may comprise a first surface that is disposed in the opening and is located on an opposite side of a surface of the interlayer dielectric layer directly contacting the plurality of conductive layers. The planarization layer comprises an upper surface having a height greater than the plurality of conductive layers.

In some embodiments, the upper surface of the planarization layer may be located on a same line as the first surface of the interlayer dielectric layer.

In some embodiments, the upper surface of the planarization layer may be recessed in a direction perpendicular to an upper surface of the substrate more than the first surface of the interlayer dielectric layer.

In some embodiments, the upper surface of the planarization layer may protrude in a direction perpendicular to an upper surface of the substrate more than the first surface of the interlayer dielectric layer.

In some embodiments, the planarization layer may be arranged as a pattern completely surrounding the opening in a plan view.

In some embodiments, the conductive layer may be located in the opening in the plan view. The plurality of conductive layers and the planarization layer may be spaced apart from each other in the plan view. The planarization layer completely surrounds the conductive layer in the plan view.

In some embodiments, the interlayer dielectric layer may cover the plurality of conductive layers in the opening in the plan view, and the interlayer dielectric layer may be located between the planarization layer and the plurality of conductive layers.

According to an embodiment of the present disclosure, a method for fabricating a display device, the method comprising: forming conductive layers on a gate insulator covering a transistor, and then forming an interlayer dielectric layer on the conductive layers; forming a planarization layer and a sacrificial layer on the interlayer dielectric layer; and removing a portion of the planarization layer and the sacrificial layer, wherein the removing the portion of the planarization layer and the sacrificial layer comprises removing the portion of the planarization layer and the sacrificial layer via an etching process comprising an etch-back process.

In some embodiments, the forming the interlayer dielectric layer on the conductive layers may comprise forming the interlayer dielectric layer so that the interlayer dielectric layer covers the conductive layers entirely and the interlayer dielectric layer has a uniform thickness with a fabrication error less than or equal to about 10%.

In some embodiments, the planarization layer may comprise an inorganic material, and the sacrificial layer comprises an organic material.

In some embodiments, the planarization layer may define an opening, and the planarization layer exposes the interlayer dielectric layer in the opening.

According to an embodiment of the present disclosure, an electronic device comprises at least one display device comprising a substrate having a transistor disposed thereon. A display device housing accommodates the at least one display device. An optical member magnifies a display image of the at least one display device or converts a light path. The at least one display device comprises a gate insulator disposed on the transistor. A plurality of conductive layers is disposed on the gate insulator. The plurality of conductive layers is spaced apart from one another. An interlayer dielectric layer is disposed on the plurality of conductive layers. The interlayer dielectric layer comprises an inorganic material. A planarization layer is disposed on the interlayer dielectric layer and defines an opening. The opening exposes the interlayer dielectric layer. The planarization layer comprises an inorganic material.

According to the embodiments of the present disclosure, a display device can provide high-resolution images, and it is possible to address the reliability issues of display devices.

According to an embodiment of the present disclosure, a display device includes a substrate having a transistor disposed thereon. A gate insulator is disposed on the transistor.

A conductive layer is disposed on the gate insulator. The conductive layer is arranged in a pattern of separated conductive islands disposed on a same line as each other. An interlayer dielectric layer is disposed on the conductive layer. The interlayer dielectric layer includes first portions disposed on the conductive islands having a first height and second portions disposed between the conductive islands having a second height less than the first height. A planarization layer is disposed on the interlayer dielectric layer on the second portions of the interlayer dielectric layer and positioned between adjacent first portions of the interlayer dielectric layer.

It should be noted that effects of the present disclosure are not limited to those described above and other effects of the present disclosure will be apparent to those skilled in the art from the following descriptions.

### BRIEF DESCRIPTION OF THE DRAWINGS

The above and other aspects and features of the present disclosure will become more apparent by describing in detail non-limiting embodiments thereof with reference to the attached drawings, in which:

FIG. 1 is a perspective view showing a head-mounted electronic device according to an embodiment of the present disclosure.

FIG. 2 is an exploded perspective view showing an example of the head-mounted electronic device of FIG. 1 according to an embodiment of the present disclosure.

FIG. 3 is a perspective view showing a head-mounted electronic device according to an embodiment of the present disclosure.

FIG. 4 is a perspective view showing a display device according to an embodiment of the present disclosure.

FIG. 5 is a cross-sectional view showing a display device according to an embodiment of the present disclosure.

FIG. 6 is a plan view showing a display layer of a display device according to an embodiment of the present disclosure.

FIG. 7 is a cross-sectional view showing the display layer taken along line X-X′ of FIG. 6 according to an embodiment of the present disclosure.

FIG. 8 is an enlarged cross-sectional view of area A of FIG. 7 according to an embodiment of the present disclosure.

FIG. 9 is an enlarged cross-sectional view of area A of FIG. 7 according to an embodiment of the present disclosure.

FIG. 10 is an enlarged cross-sectional view of area A of FIG. 7 according to an embodiment of the present disclosure.

FIG. 11 is an enlarged plan view of area C of FIG. 7 according to an embodiment of the present disclosure.

FIG. 12 is a cross-sectional view showing the display layer, taken along line X-X′ of FIG. 6, according to an embodiment of the present disclosure.

FIG. 13 is a flowchart for illustrating a method for fabricating the transistor layer in FIG. 7 according to an embodiment of the present disclosure.

FIGS. 14 and 15 are cross-sectional views showing step S100 of FIG. 13 according to embodiments of the present disclosure.

FIG. 16 is a cross-sectional view showing step S200 of FIG. 13 according to an embodiment of the present disclosure.

FIGS. 17 and 18 are cross-sectional views showing step S300 of FIG. 13 according to embodiments of the present disclosure.

FIG. 19 is a cross-sectional view showing step S400 of FIG. 13 according to an embodiment of the present disclosure.

FIG. 20 is a block diagram of an electronic device according to an embodiment of the

present disclosure.

FIG. 21 is a view showing electronic devices according to embodiments of the present disclosure.

### DETAILED DESCRIPTION OF EMBODIMENTS

The present disclosure will now be described more fully herein with reference to the accompanying drawings, in which some non-limiting embodiments of the disclosure are shown. The present disclosure may, however, be embodied in different forms and should not be construed as limited to the described embodiments set forth herein.

It is also to be understood that when a layer is referred to as being “on” another layer or substrate, it may be directly on the other layer or substrate, or one or more intervening layers may also be present. When a layer is referred to as being “directly on” another layer or substrate, no intervening layers may be present. The same reference numbers indicate the same components throughout the specification.

It is to be understood that, although the terms “first,” “second,” etc. may be used herein to describe various elements, these elements should not be limited by these terms. These terms are used to distinguish one element from another element. For instance, a first element discussed below could be termed a second element without departing from the teachings of the disclosure. Similarly, the second element could also be termed a first element.

Unless otherwise defined, all terms (including technical and scientific terms) used herein have the same meaning as commonly understood by one of ordinary skill in the art to which the inventive concept pertains. It is also to be understood that terms defined in commonly used dictionaries should be interpreted as having meanings consistent with the meanings in the context of the related art, and are expressly defined herein unless they are interpreted in an ideal or overly formal sense.

The present inventive concept relates to a source electrode and a drain electrode of a pixel transistor which contact an active layer and a lower electrode at the same time through a contact hole penetrating the active layer. With the formation of the contact hole penetrating the active layer, a thickness range is provided in which the active layer maintains high mobility of carriers such as electrons without generating defects affecting an electrical property of the active layer due to overetching. In particular, the active layer may include an oxide semiconductor material.

Hereinafter, embodiments of the present disclosure will be described in detail with reference to the accompanying drawings.

The present disclosure concerns a display device including a planarization layer that provides a flat surface over an inorganic interlayer dielectric layer that covers a plurality of conductive patterns, such as separated island-type conductive patterns. The planarization layer may increase the reliability of the display device by compensating for the height differences between portions of the interlayer dielectric layer disposed on the conductive patterns having a first height and portions of the interlayer dielectric layer disposed between the conductive patterns having a second height less than the first height.

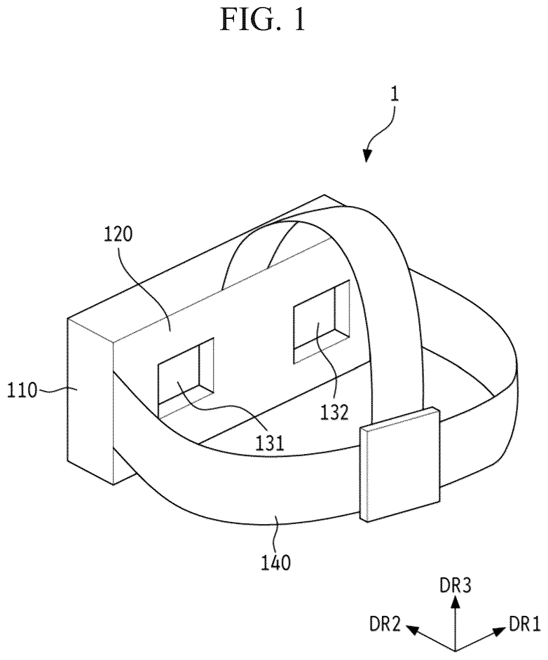

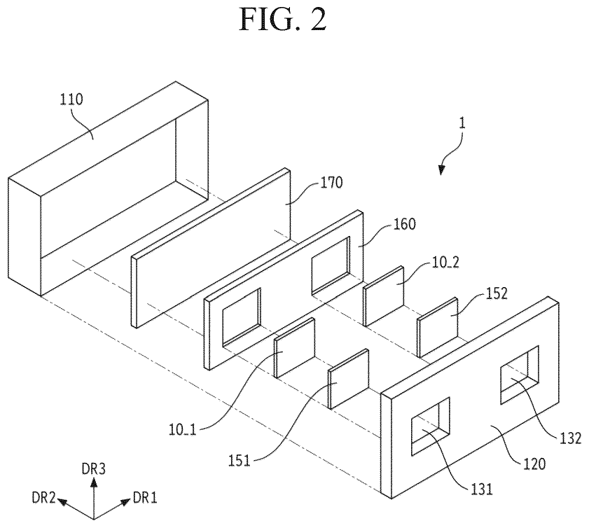

FIG. 1 is a perspective view showing a head-mounted electronic device according to an embodiment of the present disclosure. FIG. 2 is an exploded perspective view showing an example of the head-mounted electronic device of FIG. 1.

Referring to FIGS. 1 and 2, the head-mounted electronic device 1 according to an embodiment includes a display device housing 110, a housing cover 120, a first eyepiece 131, a second eyepiece 132, a head strap band 140, a first display device 10_1, a second display device 10_2, a middle frame 160, a first optical member 151, a second optical member 152, a control circuit board 170, and a connector.

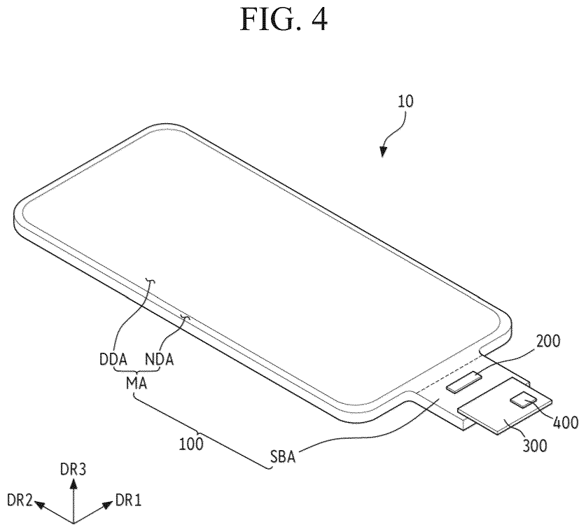

In an embodiment, the first display device 10_1 provides images to a user's left eye, and the second display device 10_2 provides images to the user's right eye. Each of the first display device 10_1 and the second display device 10_2 is substantially identical to the display device 10 described with reference to FIG. 4. Therefore, descriptions of the first display device 10_1 and the second display device 10_2 will be replaced with descriptions with reference to FIGS. 4 to 14.

The first optical member 151 may be disposed between the first display device 10_1 and the first eyepiece 131. The second optical member 152 may be disposed between the second display device 10_2 and the second eyepiece 132. Each of the first optical member 151 and the second optical member 152 may include at least one convex lens.

The middle frame 160 may be disposed between the first display device 10_1 and the control circuit board 170, and may be disposed between the second display device 10_2 and the control circuit board 170. The middle frame 160 serves to support and fix the first display device 10_1, the second display device 10_2 and the control circuit board 170.

The control circuit board 170 may be disposed between the middle frame 160 and the display device housing 110. The control circuit board 170 may be connected to (e.g., electrically connected thereto) the first display device 10_1 and the second display device 10_2 through a connector. The control circuit board 170 may convert an image source input from the outside into digital video data (DATA) and may transmit the digital video data (DATA) to the first display device 10_1 and the second display device 10_2 through the connector.

The control circuit board 170 may transmit digital video data (DATA) associated with a left eye image optimized for the user's left eye to the first display device 10_1, and may transmit digital video data (DATA) associated with a right eye image optimized for the user's right eye to the second display device 10_2. Alternatively, the control circuit board 170 may transmit the same digital video data (DATA) to the first display device 10_1 and the second display device 10_2.

The display device housing 110 accommodates the first display device 10_1, the second display device 10_2, the middle frame 160, the first optical member 151, the second optical member 152, the control circuit board 170, and the connector. The housing cover 120 is disposed to cover the open face of the housing 110. In an embodiment, the housing cover 120 may include the first eyepiece 131 where the user's left eye is placed, and the second eyepiece 132 where the user's right eye is placed. Although the first eyepiece 131 and the second eyepiece 132 are separately disposed in the example shown in FIGS. 1 and 2, embodiments of the present disclosure are not necessarily limited thereto. The first eyepiece 131 and the second eyepiece 132 may be combined into a single element.

The first eyepiece 131 may be aligned with the first display device 10_1 and the first optical member 151, and the second eyepiece 132 may be aligned with the second display device 10_2 and the second optical member 152. Therefore, a user may see virtual images of images on the first display device 10_1 magnified by the first optical member 151 through the first eyepiece 131, and virtual images of images on the second display device 10_2 magnified by the second optical member 152 through the second eyepiece 132.

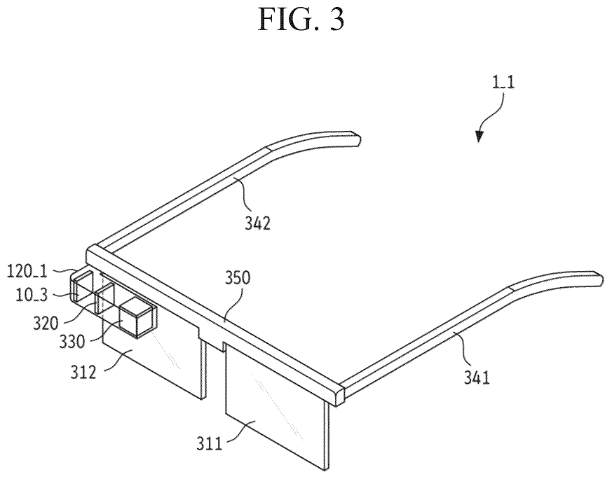

The head strap band 140 fixes the housing 110 to the user's head so that the first eyepiece 131 and the second eyepiece 132 of the housing cover 120 remain in line with the user's left and right eyes, respectively. In an embodiment, by implementing a light and small display device housing 110, the head-mounted electronic device 1 may include an eyeglasses frame as shown in FIG. 3 instead of a head strap band 140.

In addition, the head-mounted electronic device 1 may further include a battery for supplying power, an external memory slot for inserting an external memory, and an external connection port and a wireless communication module for receiving an image source. In an embodiment, the external connection port may be a USB (universe serial bus) terminal, a display port, or an HDMI (high-definition multimedia interface) terminal. The wireless communication module may be a 5G communication module, a 4G communication module, a Wi-Fi module, or a Bluetooth module.

FIG. 3 is a perspective view showing a head-mounted electronic device according to an embodiment of the present disclosure.

Referring to FIG. 3, the head-mounted electronic device 1_1 according to an embodiment may be a glasses-type display device with a light and small display device housing 120_1. The head-mounted electronic device 1_1 according to an embodiment may include a display device 10_3, a left-eye lens 311, a right-eye lens 312, a support frame 350, eyeglass temples (e.g., arms) 341 and 342, an optical member 320, a light path conversion member 330, and a display device housing 120_1.

The display device 10_3 shown in FIG. 3 is substantially identical to the display device 10 described with reference to FIG. 4.

The display device housing 120_1 may include the display device 10_3, the optical member 320, and the light path conversion member 330. In an embodiment, the images displayed on the display device 10_3 may be enlarged by the optical member 320, and the light path of the images are converted by the light path conversion member 330 to be provided to the user's right eye through the right eye lens 312. As a result, the user can see (e.g., visualize), with the right eye, augmented reality images that combine virtual images displayed on the display device 10_3 and real world images viewed through the right eye lens 312.

Although the display device housing 120_1 is disposed at the right end of the support frame 350 in an embodiment shown in FIG. 3, embodiments of the present disclosure are not necessarily limited thereto. For example, in an embodiment the display device housing 120_1 may be disposed at the left end of the support frame 350. In this embodiment, images displayed on the display device 10_3 may be provided to the user's left eye. Alternatively, the display device housing 120_1 may be disposed at both the left and right ends of the support frame 350, respectively. In this embodiment, the user can watch images displayed on the display device 10_3 through both the left and right eyes.

FIG. 4 is a perspective view showing a display device according to an embodiment.

Referring to FIG. 4, in an embodiment a display device 10 may be applied to various different portable electronic devices, such as a mobile phone, a smart phone, a tablet PC, a mobile communications terminal, an electronic notebook, an electronic book, a portable multimedia player (PMP), a navigation device and an ultra mobile PC (UMPC). For example, in an embodiment the display device 10 may be used as a display unit of a television, a laptop computer, a monitor, an electronic billboard, or the Internet of Things (IOT). For another example, the display device 10 may be applied to wearable devices such as a smart watch, a watch phone, a glasses-type display, and a head-mounted display (HMD) device. However, embodiments of the present disclosure are not necessarily limited thereto and the electronic device that the display device 10 may be applied to may be various different small-sized, medium-sized or large-sized electronic devices.

The display device 10 may have a shape similarly to a quadrangular shape when viewed from the top (e.g., in a plan view). For example, the display device 10 may have a shape similar to a rectangle having shorter sides in a first direction DR1 and longer sides in a second direction DR2. In an embodiment, the corners where the shorter sides in the first direction DR1 meet the longer sides in the second direction DR2 may be rounded with a predetermined curvature or may be a right angle. The shape of the display device 10 when viewed from the top is not necessarily limited to a quadrangular shape, but may be formed in various different shapes, such as a shape similar to other polygonal shapes, a circular shape, or an elliptical shape.

The display device 10 may include a display panel 100, a display driver 200, a circuit board 300 and a touch driver 400.

The display panel 100 may include a main area MA and a subsidiary area SBA. The main area MA may include the display area DDA including pixels for displaying images, and the non-display area NDA located around the display area DDA (e.g., in a plan view).

The display area DDA may output light from a plurality of emission areas or a plurality of openings to be described later. For example, the display panel 100 may include pixel circuits including switching elements, a pixel-defining layer that defines the emission areas or the openings, and self-light-emitting elements. For example, in an embodiment the self-light-emitting element may include, but is not necessarily limited to, at least one of: an organic light-emitting diode including an organic emissive layer, a quantum-dot light-emitting diode (quantum LED) including a quantum-dot emissive layer, an inorganic light-emitting diode (inorganic LED) including an inorganic semiconductor, and a micro light-emitting diode (micro LED). In the following drawings, it is illustrated that the self-luminous element is an organic light-emitting diode.

The non-display area NDA may be disposed on the outer side of the display area DDA (e.g., in a plan view). The non-display area NDA may be defined as the edge area of the main area MA of the display panel 100.

The subsidiary area SBA may be extended from one side of the main area MA. For example, in an embodiment shown in FIG. 4, the subsidiary area SBA extends from a lower side of the main area MA (e.g., in a direction opposite to the second direction DR2). The subsidiary area SUB may include a flexible material that can be bent, folded, or rolled. For example, when the subsidiary area SBA is bent, the subsidiary area SBA may overlap the main area MA in the thickness direction (e.g., third direction DR3). The subsidiary area SBA may include pads connected to the display driver 200 and the circuit board 300. However, embodiments of the present disclosure are not necessarily limited thereto. For example, in an embodiment, the display device 10 may not include a subsidiary area SBA and the display driver 200 and the pads may be disposed in the non-display area NDA.

The display driver 200 may output signals and voltages for driving the display panel 100. In an embodiment, the display driver 200 may be implemented as an integrated circuit (IC) and may be attached on the display panel 100 by a chip-on-glass (COG) technique, a chip-on-plastic (COP) technique, or ultrasonic bonding. For example, the display driver 200 may be located in the subsidiary area SBA and may overlap with the main area MA in the thickness direction when the subsidiary area SBA is in a bent orientation. For another example, the display driver 200 may be mounted on the circuit board 300.

In an embodiment, the circuit board 300 may be attached on the pad area of the display panel 100 using an anisotropic conductive film (ACF). The circuit board 300 may be a flexible printed circuit board (FPCB), a printed circuit board (PCB), or a flexible film such as a chip-on-film (COF).

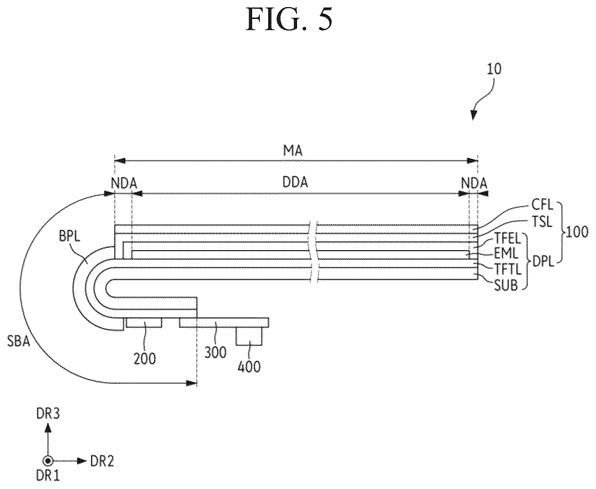

The touch driver 400 may be mounted on (e.g., disposed on) the circuit board 300. The touch driver 400 may be connected to a touch sensor layer TSL (see FIG. 5) for detecting and driving a touch on the display device 10.

FIG. 5 is a cross-sectional view showing a display device according to an embodiment of the present disclosure.

Referring to FIG. 5, in an embodiment the display panel 100 may include a display layer DPL, a touch sensor layer TSL, and a color filter layer CFL. The display layer DPL may include a substrate SUB, a transistor layer TFTL, a display element layer EML, and a thin-film encapsulation layer TFEL.

The substrate SUB may be a base substrate or a base member. In an embodiment, the substrate SUB may be a flexible substrate that can be bent, folded, or rolled. For example, the substrate SUB may include, but is not necessarily limited to, a polymer resin such as polyimide PI. However, embodiments of the present disclosure are not necessarily limited thereto. For example, in an embodiment, the substrate SUB may include a glass material or a metal material.

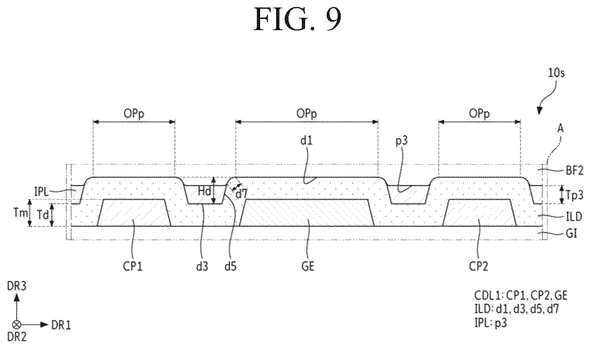

The transistor layer TFTL may be disposed on the substrate SUB (e.g., disposed directly thereon in the third direction DR3). In an embodiment, the transistor layer TFTL may be located in the display area DDA, the non-display area NDA and the subsidiary area SBA. The transistor layer TFTL may include a plurality of transistors TFT (see FIG. 9).

The display element layer EML may be disposed on the transistor layer TFTL (e.g., disposed directly thereon in the third direction DR3). The display element layer EML may be located in the display area DDA. In an embodiment, the display element layer EML may include, but is not necessarily limited to, at least one of: an organic light-emitting diode including an organic emissive layer, a quantum-dot light-emitting diode (quantum LED) including a quantum-dot emissive layer, an inorganic light-emitting diode (inorganic LED) including an inorganic semiconductor, and a micro light-emitting diode (micro LED).

The thin-film encapsulation layer TFEL may be located on the display element layer EML (e.g., disposed directly thereon in the third direction DR3). The thin-film encapsulation layer TFEL may be located in the display area DDA and the non-display area NDA. The thin-film encapsulation layer TFEL may cover the upper and side surfaces of the display element layer EML, and can protect the display element layer EML from outside oxygen and moisture. The thin-film encapsulation layer TFEL may include at least one inorganic film and at least one organic film for encapsulating the display element layer EML. However, embodiments of the present disclosure are not necessarily limited thereto. For example, the display device 10 may not include the thin-film encapsulation layer TFEL in some implementations.

The touch sensor layer TSL may be disposed on the thin-film encapsulation layer TFEL. The touch sensor layer TSL may be located across the display area DDA and the non-display area NDA (e.g., in the third direction DR3). The touch sensor layer TSL may sense a user's touch by mutual capacitance sensing or self-capacitance sensing. However, embodiments of the present disclosure are not necessarily limited thereto. For example, the display device 10 may not include the touch sensor layer TSL in some implementations.

The color filter layer CFL may be disposed on the touch sensor layer TSL (e.g., disposed directly thereon in the third direction DR3). In an embodiment, the color filter layer CFL may be located in the display area DDA and the non-display area NDA. The color filter layer CFL may absorb some of lights introduced from the outside (e.g., the external environment) of the display device 10 to reduce the reflection of external light. Accordingly, the color filter layer CFL can prevent distortion of colors due to the reflection of external light.

In an embodiment in which the color filter layer CFL is disposed directly on the touch sensor layer TSL, the display device 10 may not have a separate substrate for the color filter layer CFL. Therefore, the thickness of the display device 10 can be relatively small. However, embodiments of the present disclosure are not necessarily limited thereto. For example, the display device 10 may not include the color filter layer CFL in some implementations.

As shown in FIG. 5, a portion of the display panel 100 overlapping with the subsidiary area SBA may be bent. In an embodiment, when a portion of the display panel 100 has a bent orientation, the display driver 200, the circuit board 300 and the touch driver 400 may overlap with the main area MA in the third direction DR3.

When a part of the display panel 100 has a bent orientation, the bending protection layer BPL can protect the underlying structure located in the subsidiary area SBA from bending stress.

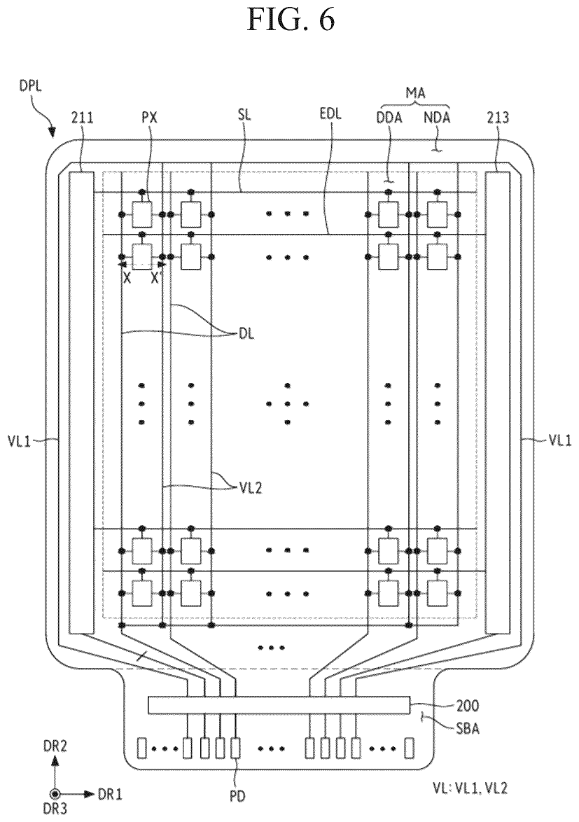

FIG. 6 is a plan view showing a display layer of a display device according to an embodiment of the present disclosure.

Referring to FIG. 6, the display layer DPL may include a plurality of pixels PX located in the display area DDA, and a plurality of voltage lines VL, a plurality of scan lines SL, a plurality of emission control lines EDL and a plurality of data lines DL connected to the plurality of pixels PX.

In an embodiment, the plurality of scan lines SL may extend longitudinally in the first direction DR1 and may be spaced apart from one another in the second direction DR2 intersecting the first direction DR1. The scan lines may be arranged along the second direction DR2. The scan lines SL may sequentially supply a scan signal to the pixels PX.

In an embodiment, the emission control lines EDL may extend longitudinally in the first direction DR1 and may be spaced apart from one another in the second direction DR2. The emission control lines EDL may be arranged along the second direction DR2. The emission control lines EDL may sequentially supply an emission control signal to the pixels PX.

In an embodiment, the data lines DL may extend longitudinally in the second direction DR2 and may be spaced apart from one another in the first direction DR1. The data lines DL may be arranged along the first direction DR1. The data lines DL may apply data voltage to the pixels PX. The data voltage may determine the luminance of each of the plurality of pixels PX.

In an embodiment, the voltage lines VL may include a main voltage line VL1 and a subsidiary voltage line VL2. At least one of the first supply voltage (e.g., a high-level voltage) or the second supply voltage (e.g., a low-level voltage) may be transmitted to the subsidiary voltage line VL2 through the main voltage line VL1 located in the non-display area NDA. In the following description, the main voltage line VL1 and the subsidiary voltage line VL2 may be collectively referred to as voltage lines VL.

The non-display area NDA may surround the display area DDA (e.g., in a plan view). The non-display area NDA may include a scan driver 211, an emission control driver 213.

The scan driver 211 may be disposed on an outer side of the display area DDA or on a side of the non-display area NDA (e.g., in a plan view). The scan driver 211 may include a plurality of driving transistors for generating gate signals based on a gate control signal.

In an embodiment, the emission control driver 213 may be disposed on the opposite outer side of the display area DDA or on the opposite side of the non-display area NDA (e.g., in a plan view). The emission control driver 213 may include a plurality of emission control transistors for generating emission signals based on the emission control signal.

The display layer DPL according to an embodiment may include the display driver 200 and a plurality of pad electrodes PD located in the subsidiary area SBA. The plurality of pad electrodes PD may be spaced apart from one another in the first direction DR1, and the pad electrodes PD may be connected to different lines, respectively.

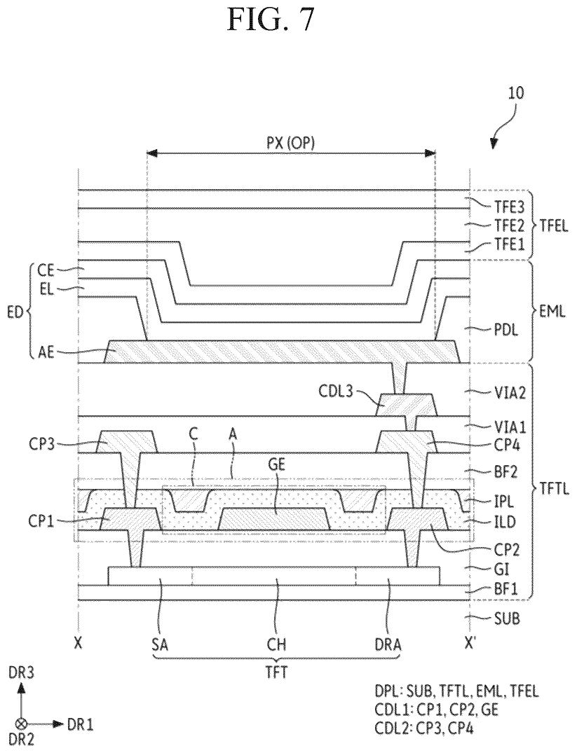

FIG. 7 is a cross-sectional view showing an embodiment of the display layer taken along line X-X′ of FIG. 6. FIG. 7 is a cross-sectional view showing an embodiment of the display layer DPL included in a pixel PX, and schematically shows the substrate SUB, the transistor layer TFTL, the display element layer EML, and the thin-film encapsulation layer TFEL. The substrate SUB has been described above with reference to FIG. 5; and, therefore, redundant descriptions will be omitted for economy of description.

Referring to FIG. 7 in conjunction with FIGS. 1 to 6, the transistor layer TFTL may be disposed on the substrate SUB.

The transistor layer TFTL may be disposed on the substrate SUB (e.g., disposed directly thereon in the third direction DR3). In an embodiment, the transistor layer TFTL may include a first buffer layer BF1, a transistor TFT, a gate insulator GI, a first conductive layer CDL1, an interlayer dielectric layer ILD, a planarization layer IPL, a second buffer layer BF2, a second conductive layer CDL2, a first via layer VIA1, a third conductive layer CDL3, and a second via layer VIA2.

The first buffer layer BF1 may be disposed on the substrate SUB (e.g., disposed directly thereon in the third direction DR3). The first buffer layer BF1 may prevent the permeation of air or moisture through the substrate SUB. In an embodiment, the first buffer layer BF1 may include multiple inorganic films alternately stacked on one another (e.g., in the third direction DR3).

For example, in an embodiment the first buffer layer BF1 may include silicon nitride (e.g., Si₃N₄ or SiNx), silicon oxide (e.g., SiO₂ or SiOx), silicon oxynitride (e.g., SiON), titanium oxide, aluminum oxide, or other inorganic insulating materials.

The transistor TFT may be disposed on the first buffer layer BF1 (e.g., disposed directly thereon in the third direction DR3). The transistor TFT may be a driving transistor of the pixel PX. The transistor TFT may include a semiconductor material. For example, in an embodiment the transistor TFT may include polysilicon, amorphous silicon, oxide semiconductor, or other semiconductor materials.

The transistor TFT may include a channel region CH that is in line with (e.g., overlaps) a gate electrode GE in the third direction DR3. In addition, the transistor TFT may include a source region SA and a drain region DRA located on the both sides of the channel region CH in the first direction DR1, respectively. During the process of fabricating the display device 10, the source region SA and the drain region DRA may become conductive to have higher conductivity than the channel region CH by doping or another method.

The gate insulator GI may be disposed over the transistors TFT. The gate insulator GI may prevent permeation of air or moisture. For example, in an embodiment the gate insulator GI may include a plurality of inorganic films stacked on one another alternately (e.g., in the third direction DR3).

The gate insulator GI may include an inorganic insulating material. Accordingly, the gate insulator GI may electrically insulate the gate electrode GE from the transistor TFT.

For example, in an embodiment the gate insulator GI may include silicon nitride (e.g., Si₃N₄ or SiNx), silicon oxide (e.g., SiO₂ or SiOx), silicon oxynitride (e.g., SiON), titanium oxide, aluminum oxide, or other inorganic insulating materials.

The first conductive layer CDL1 may be disposed on the gate insulator GI (e.g., disposed directly thereon in the third direction DR3). In an embodiment, the first conductive layer CDL1 may include a gate electrode GE, a first conductive portion CP1 and a second conductive portion CP2. The first conductive layer CDL1 may be comprised of a conductive material, such as a conductive metal.

The gate electrode GE may be disposed on the gate insulator GI (e.g., disposed directly thereon in the third direction DR3). The gate electrode GE may overlap with the channel region CH of the transistor TFT with the gate insulator GI therebetween in the third direction DR3.

The gate electrode GE may include a conductive material. For example, in an embodiment the gate electrode GE may include at least one of molybdenum (Mo), aluminum (Al), chromium (Cr), gold (Au), silver (Ag), titanium (Ti), nickel (Ni), neodymium (Nd), copper (Cu) and other metals, alloys thereof, or other conductive materials.

The first conductive portion CP1 and the second conductive portion CP2 may be electrically connected to the transistor TFT. In an embodiment, the first conductive portion CP1 may be connected to the source region SA of the transistor TFT through a contact hole penetrating the gate insulator GI, and the second conductive portion CP2 may be connected to the drain region DRA of the transistor TFT through a contact hole penetrating the gate insulator GI. For example, the first conductive portion CPI may be a source electrode, and the second conductive portion CP2 may be a drain electrode.

The first conductive portion CP1 and the second conductive portion CP2 may include a conductive material. For example, in an embodiment the first conductive portion CPI and the second conductive portion CP2 may include at least one of molybdenum (Mo), aluminum (Al), chromium (Cr), gold (Au), silver (Ag), titanium (Ti), nickel (Ni), neodymium (Nd), copper (Cu) and other metals, alloys thereof, or other conductive materials.

The interlayer dielectric film ILD may be disposed on (e.g., disposed directly thereon) the first conductive layer CDL1. The interlayer dielectric layer ILD may entirely cover the first conductive layer CDL1 and the gate insulator GI. In an embodiment, the interlayer dielectric layer ILD may include height differences among different portions of the interlayer dielectric layer ILD. More detailed descriptions will be given below.

The interlayer dielectric layer ILD may prevent the permeation of air or moisture from the outside (e.g., the external environment) and can protect the first conductive layer CDL1 during the fabrication process.

The interlayer dielectric layer ILD may include an inorganic insulating material. For example, in an embodiment the interlayer dielectric layer ILD may include silicon nitride (e.g., Si₃N₄ or SiNx), silicon oxide (e.g., SiO₂ or SiOx), silicon oxynitride (e.g., SiON), titanium oxide, aluminum oxide, or other inorganic insulating materials.

The planarization layer IPL may be disposed on (e.g., disposed directly thereon) the interlayer dielectric layer ILD. The planarization layer IPL may provide a flat surface over the interlayer dielectric layer ILD having height differences. More detailed descriptions will be given below.

The planarization layer IPL may include an inorganic insulating material. For example, in an embodiment the planarization layer IPL may include silicon nitride (e.g., Si₃N₄ or SiNx), silicon oxide (e.g., SiO₂ or SiOx), silicon oxynitride (e.g., SiON), titanium oxide, aluminum oxide, or other inorganic insulating materials.

The second buffer layer BF2 may be disposed on the interlayer dielectric layer ILD and the planarization layer IPL (e.g., disposed directly thereon in the third direction DR3). However, embodiments of the present disclosure are not necessarily limited thereto. For example, in some embodiments the display device 10 may not include the second buffer layer BF2. The second buffer layer BF2 may include the same material as the first buffer layer BF1. Therefore, redundant descriptions will be omitted.

The second conductive layer CDL2 may be disposed on the second buffer layer BF2 (e.g., disposed directly thereon in the third direction DR3). The second conductive layer CDL2 may include a third conductive portion CP3 and a fourth conductive portion CP4. The third conductive portion CP3 and the fourth conductive portion CP4 may include at least one of a variety of lines disposed in the display area DDA of FIG. 6.

The second conductive layer CDL2 may include a conductive material, such as a conductive metal. For example, in an embodiment the second conductive layer CDL2 may include at least one of molybdenum (Mo), aluminum (Al), chromium (Cr), gold (Au), silver (Ag), titanium (Ti), nickel (Ni), neodymium (Nd), copper (Cu) and other metals, alloys thereof, or other conductive materials.

In an embodiment, the third conductive portion CP3 included in the second conductive layer CDL2 may be connected to the first conductive portion CP1 of the first conductive layer CDL1 through a contact hole penetrating the interlayer dielectric layer ILD and the second buffer layer BF2. The fourth conductive portion CP4 included in the second conductive layer CDL2 may be connected to the second conductive portion CP2 of the first conductive layer CDL1 through a contact hole penetrating the interlayer dielectric layer ILD and the second buffer layer BF2.

The first via layer VIA1 may be located on (e.g., disposed directly thereon in the third direction DR3) the second buffer layer BF2 and may cover the second conductive layer CDL2. The first via layer VIA1 may provide a flat surface over the underlying structures.

The first via layer VIA1 may include an organic material. For example, in an embodiment the first via layer VIA1 may include an acryl resin, an epoxy resin, a phenolic resin, a polyamide resin, a polyimide resin, etc.

The third conductive layer CDL3 may be disposed on the first via layer VIA1 (e.g., disposed directly thereon in the third direction DR3). The third conductive layer CDL3 may be a connecting electrode that electrically connects the second conductive layer CDL2 with the anode electrode AE. In an embodiment, the third conductive layer CDL3 may be electrically connected to the second conductive layer CDL2 through a contact hole penetrating the first via layer VIA1.

The second via layer VIA2 may be disposed on the first via layer VIA1 (e.g., disposed directly thereon in the third direction DR3) and may cover the third conductive layer CDL3. The second via layer VIA2 may provide a flat surface over the underlying structures.

The second via layer VIA2 may include an organic material. For example, in an embodiment the second via layer VIA2 may include an acryl resin, an epoxy resin, a phenolic resin, a polyamide resin, a polyimide resin, etc.

The display element layer EML may be disposed on the transistor layer TFTL (e.g., disposed directly thereon in the third direction DR3). The display element layer EML may include a light-emitting element ED and a pixel-defining layer PDL. The light-emitting element ED may include the anode electrode AE, an emissive layer EL, and a cathode electrode CE.

The anode electrode AE of the light-emitting element ED may be disposed on the second via layer VIA2 (e.g., disposed directly thereon in the third direction DR3). In an embodiment, the anode electrode AE may be connected to the third conductive layer CDL3 through a contact hole penetrating through the second via layer VIA2.

In an embodiment, the anode electrode AE may be made up of a single layer of silver (Ag), molybdenum (Mo), titanium (Ti), copper (Cu) or aluminum (Al), or may be made up of a stack structure of aluminum and titanium (Ti/Al/Ti), a stack structure of aluminum and ITO (ITO/AI/ITO), an APC alloy and a stack structure of an APC alloy and ITO (ITO/APC/ITO) to increase the reflectivity. The APC alloy may be an alloy of silver (Ag), palladium (Pd) and copper (Cu).

The pixel-defining layer PDL may be disposed on the second via layer VIA2 (e.g., disposed directly thereon in the third direction DR3). The pixel-defining layer PDL defines a pixel opening OP and may expose the anode electrode AE in the pixel opening OP. In an embodiment, the pixel-defining layer PDL may cover the edges of the anode electrode AE and the pixel opening OP may expose a central portion of the anode electrode AE.

The pixel-defining layer PDL may include an organic material or an inorganic material.

For example, in an embodiment in which the pixel-defining layer PDL includes an organic material, the pixel-defining layer PDL may include an acryl resin, an epoxy resin, a phenolic resin, a polyamide resin and a polyimide resin, etc.

For example, in an embodiment in which the pixel-defining layer PDL includes an inorganic material, the pixel-defining layer PDL may include silicon nitride (e.g., Si₃N₄ or SiNx), silicon oxide (e.g., SiO₂ or SiOx), silicon oxynitride (e.g., SiON), titanium oxide, aluminum oxide, or other inorganic insulating materials.

The emissive layer EL of the light-emitting element ED may be located on (e.g., disposed directly thereon in the third direction DR3) the anode electrode AE. The emissive layer EL may include an organic material to emit light of a certain color. For example, in an embodiment the emissive layer EL may include a hole transporting layer, an organic material layer, and an electron transporting layer. The organic material layer may include a host and a dopant. The organic material layer may include a material that emits a predetermined light, and may be formed using a phosphor or a fluorescent material.

The cathode electrode CE of the light-emitting element ED may be located on the emissive layer EL (e.g., disposed thereon in the third direction DR3). The cathode electrode CE may be located to cover the emissive layer EL. The cathode electrode CE may be a common layer disposed across a plurality of emissive layers EL.

In an embodiment, the cathode electrode CE may be formed of a transparent conductive material (TCP) such as ITO and IZO that can transmit light, or a semi-transmissive conductive material such as magnesium (Mg), silver (Ag) and an alloy of magnesium (Mg) and silver (Ag). In an embodiment in which the cathode electrode CE is made of a semi-transmissive metal material, the light extraction efficiency can be increased by using microcavities.

The thin-film encapsulation layer TFEL may be formed on the display element layer EML (e.g., disposed directly thereon in the third direction DR3). The thin-film encapsulation layer TFEL may include at least one inorganic film to prevent permeation of oxygen or moisture into the display element layer EML. The thin-film encapsulation layer TFEL may include at least one organic film to protect the display element layer EML from particles such as dust.

In an embodiment, the thin-film encapsulation layer TFEL may include a first encapsulation layer TFE1, a second encapsulation layer TFE2 and a third encapsulation layer TFE3.

In an embodiment, the first encapsulation layer TFE1 may be located on (e.g., disposed directly thereon) the cathode electrode CE and may entirely cover the cathode electrode CE.

The first encapsulation layer TFE1 may include an inorganic insulating material. For example, in an embodiment the first encapsulation layer TFE1 may include silicon nitride (e.g., Si₃N₄ or SiNx), silicon oxide (e.g., SiO₂ or SiOx), silicon oxynitride (e.g., SiON), titanium oxide, aluminum oxide, or other inorganic insulating materials.

The second encapsulation layer TFE2 may be located on (e.g., disposed directly thereon) the first encapsulation layer TFE1 and may entirely cover the first encapsulation layer TFE1. The second encapsulation layer TFE2 may provide a flat surface over the first encapsulation layer TFE1.

In an embodiment, the second encapsulation layer TFE2 may include an organic material, and may be, for example, an organic film such as an acrylic resin, an epoxy resin, a silicone resin, a silicone-acryl resin, a phenolic resin, a polyamide resin, and a polyimide resin.

The third encapsulation layer TFE3 may be located on (e.g., disposed directly thereon) the second encapsulation layer TFE2 and may entirely cover the second encapsulation layer TFE2.

The third encapsulation layer TFE3 may include an inorganic insulating material. For example, in an embodiment the first encapsulation layer TFE1 may include silicon nitride (e.g., Si₃N₄ or SiNx), silicon oxide (e.g., SiO₂ or SiOx), silicon oxynitride (e.g., SiON), titanium oxide, aluminum oxide, or other inorganic insulating materials.

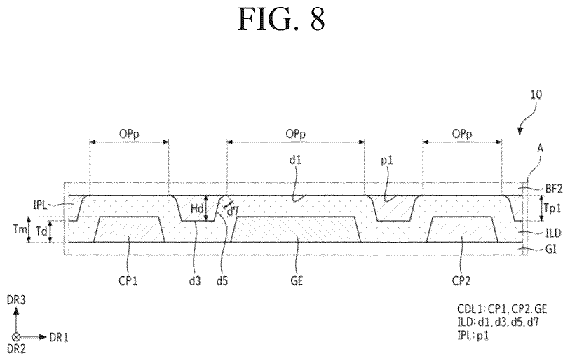

FIG. 8 is an enlarged cross-sectional view of area A of FIG. 7. Hereinafter, the structures of the first conductive layer CDL1, the interlayer dielectric layer ILD and the planarization layer IPL will be described in detail.

Referring to FIG. 8 in conjunction with FIGS. 1 to 7, the first conductive layer CDL1 may be disposed on the gate insulator GI (e.g., disposed directly thereon in the third direction DR3). The first conductive portion CP1, the second conductive portion CP2 and the gate electrode GE included in the first conductive layer CDL1 may be a conductive pattern including a conductive material. The above-described conductive pattern may refer to a pattern of separated conductive islands.

According to an embodiment of the present disclosure, the first conductive portion CP1, the second conductive portion CP2 and the gate electrode GE included in the first conductive layer CDL1 may be located on the same line in the first direction DR1. For example, upper and lower surfaces of the first conductive portion CP1, the second conductive portion CP2 and the gate electrode GE may be co-planar with each other (e.g., in the third direction DR3) and may be disposed on a same layer which extends in the first direction DR1 which is a direction parallel to an upper surface of the substrate SUB. The first conductive portion CP1, the second conductive portion CP2 and the gate electrode GE may be spaced apart from one another (e.g., in the first direction DR1). Accordingly, a plurality of conductive patterns may be disposed on the gate insulator GI, and the conductive patterns may be spaced apart from each other in the first direction DR1.

According to an embodiment of the present disclosure, the first conductive portion CP1, the second conductive portion CP2 and the gate electrode GE included in the first conductive layer CDL1 may have the same thickness Tm as each other (e.g., length in the third direction DR3). It should be noted, however, that the widths of the first conductive portion CP1, the second conductive portion CP2 and the gate electrode GE in the first direction DR1 may be different from one another.

The interlayer dielectric layer ILD may be disposed on (e.g., disposed directly thereon) the first conductive layer CDL1 and may entirely cover the first conductive portion CP1, the second conductive portion CP2 and the gate electrode GE, such as by directly contacting an entirety of upper surfaces and lateral side surfaces of the each of the first conductive layers CDL1. The interlayer dielectric layer ILD may entirely cover a plurality of conductive patterns disposed thereunder. In an embodiment, the interlayer dielectric layer ILD may be disposed on an entirety of the substate SUB.

According to an embodiment of the present disclosure, the interlayer dielectric layer ILD may be formed with a uniform thickness Td (e.g., length in the third direction DR3) along the profile formed by the underlying structures having height differences. Accordingly, the interlayer dielectric layer ILD may include different heights conforming to the profile formed by the underlying structures. It should be noted that the meaning of the uniformity of the thickness (Td) of the interlayer dielectric layer ILD may allow a process error (e.g., a fabrication error) range of about 10% or less.

For example, the interlayer dielectric layer ILD may cover along the height differences formed between the plurality of first conductive layers CDL1 and the gate insulator GI. Accordingly, the interlayer dielectric layer ILD may include height differences Hd, such as height differences between portions of the interlayer dielectric layer ILD that are disposed in an opening OPp of the planarization layer IPL and portions of the interlayer dielectric layer ILD that are not disposed in the opening Opp of the planarization layer IPL.

In an embodiment, the interlayer dielectric layer ILD may include a first surface d1 and a second surface d3.

The first surface d1 may be a surface of a portion of the interlayer dielectric layer ILD (e.g., a first portion) located such that it overlaps with the first conductive layer CDL1 in the third direction DR3. The first surface d1 may be an opposite surface of the surface in direct contact with the first conductive layer CDL1. For example, the first surface d1 may face one side in the third direction DR3. The first surface d1 may be located in an opening OPp of the planarization layer IPL to be described later. The first surface d1 may have a first height.

The second surface d3 may be a surface of a portion of the interlayer dielectric layer ILD (e.g., a second portion) located such that it does not overlap with the first conductive layer CDL1 in the third direction DR3 and is disposed between conductive layers, such as between a pattern of separated conductive islands on a same line, of the first conductive layer CDL1. The second surface d3 may be the opposite surface of the surface in direct contact with the gate insulator GI. For example, the second surface d3 may face one side in the third direction DR3. The second surface d3 may not overlap with an opening OPp of the planarization layer IPL. The second surface d3 may be in direct contact with the planarization layer IPL. The second surface d3 may have a second height that is less than the first height of the first surface d1.

The first surface d1 and the second surface d3 of the interlayer dielectric layer ILD may be located on different lines in the first direction DR1. The height difference between one surface where the first surface d1 is located and one surface where the second surface d3 is located in the first direction DR1 may mean a height difference Hd of the interlayer dielectric layer ILD. The height difference Hd of the interlayer dielectric layer ILD may be less than or equal to the thickness Tm of the first conductive layer CDL1.

According to an embodiment of the present disclosure, the interlayer dielectric layer ILD may further include a first side surface d5 and a second side surface d7. The first side surface d5 may be directly connected to the second surface d3 and may face the planarization layer IPL in the first direction DR1. The second side surface d7 may be directly connected to the first surface d1 and may connect the first surface d1 with the first side surface d5.

According to an embodiment of the present disclosure, the second side surface d7 of the interlayer dielectric layer ILD may be a curved surface. During the process of fabricating the display device 10, the second side surface d7 may be formed as a curved surface as a part of the interlayer dielectric layer ILD is exposed to an etch-back process in an etching process. Such a fabrication process will be described later.

Typically, in a display device applied to a high-resolution device, a plurality of first conductive layers CDL1 may be formed in a narrow area. This may mean that the first conductive layers CDL1 formed in a conductive pattern are arranged at a narrow interval. Accordingly, the interlayer dielectric layer ILD may cover the height differences formed by the first conductive layers CDL1, and accordingly the interlayer dielectric layer ILD may also include height differences Hd. The height differences in the interlayer dielectric layer ILD may be differences in height between portions that do not overlap with the opening OPp of the planarization layer IPL and portions that overlap with the opening OPp of the planarization layer IPL.

According to an embodiment of the present disclosure, the display device 10 may include the planarization layer IPL that provides a flat surface over the height differences Hd of the interlayer dielectric layer ILD.

For example, if insulating layers having height differences are repeatedly stacked in the third direction DR3 on the conductive patterns included in a high-resolution display device, this may cause reliability defects in the display device. For example, if insulating layers having height differences are stacked on the conductive patterns included in a high-resolution display device without a planarization layer, this may cause reliability defects in the display device (e.g., a defect due to a part of the conductive patterns not being covered and exposed and/or a defect due to uneven exposure of the height differences of the conductive pattern, etc.).

Accordingly, the planarization layer IPL according to an embodiment may planarize height differences in the interlayer dielectric layer ILD and reduce reliability defects of the display device 10.

According to an embodiment of the present disclosure, the planarization layer IPL may be disposed between the adjacent conductive layers of the first conductive layers CDL1 that are spaced apart from one another (e.g., in a plan view). In the cross-sectional view, the planarization layer IPL may define an opening OPp and the interlayer dielectric layer ILD, such as the first surface d1 of the interlayer dielectric layer ILD, may be exposed in the opening OPp. For example, the planarization layer IPL may be in the form of a single pattern surrounding the opening OPp.

According to an embodiment of the present disclosure, the first conductive layer CDL1 may be located such that it overlaps with the opening OPp, and the planarization layer IPL may completely surround the first conductive layer CDL1 (e.g., in a plan view). For example, each of the pattern of conductive islands of the first conductive layer CDL1, such as the gate electrode GE, the first conductive portion CP1 and the second conductive portion CP2, may overlap the opening OPp of the planarization layer IPL.

According to an embodiment of the present disclosure, the planarization layer IPL may be formed to entirely cover the interlayer dielectric layer ILD and then formed into a shape as shown in FIG. 8 via a subsequent etching process during the process of fabricating the display device 10. Such a fabrication process will be described later.

According to some embodiments, the thickness Tp1 of the planarization layer IPL may have a value in a range from about 50% to about 150% of the height difference Hd of the interlayer dielectric layer ILD.

For example, if the thickness Tp1 of the planarization layer IPL has a value less than about 50% or more than about 150% of the height difference Hd of the interlayer dielectric layer ILD, the display device 10 may have reliability defects.

In some embodiments, the planarization layer IPL may include an upper surface p1 facing one side in the third direction DR3. The upper surface p1 of the planarization layer IPL may be located on the same line as the first surface d1 of the interlayer dielectric layer ILD. For example, a height of the upper surface p1 of the planarization layer IPL from a top surface of the substrate SUB may be substantially the same as the height of the first surface d1 of the interlayer dielectric layer ILD from the top surface of the substrate SUB. For example, the upper surface p1 of the planarization layer IPL may be extended from the first surface d1 of the interlayer dielectric layer ILD (e.g., in the first direction DR1). In an embodiment, the interlayer dielectric layer ILD and the planarization layer IPL may form a flat surface on one side in the third direction DR3.

In some embodiments, the planarization layer IPL may cover the second side surface d7 of the interlayer dielectric layer ILD.

As described above, the planarization layer IPL may include an inorganic material. The planarization layer IPL may include the same material as the interlayer dielectric layer ILD, or may include a different material from the interlayer dielectric layer ILD.

The second buffer layer BF2 may be disposed in direct contact with the interlayer dielectric layer ILD and the planarization layer IPL, such as upper surfaces of the interlayer dielectric layer ILD and the planarization layer IPL. According to an embodiment of the present disclosure, the second buffer layer BF2 may be formed substantially flat as it is disposed on the planarization layer IPL.

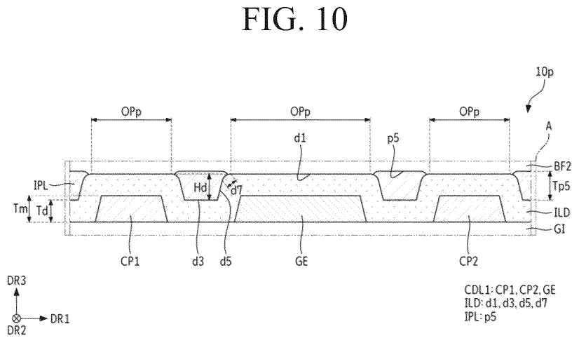

FIGS. 9 and 10 are enlarged cross-sectional views of area A of FIG. 7 according to an embodiment.

Referring to FIG. 9 in conjunction with FIGS. 1 to 8, a planarization layer IPL included in a display device 10s of FIG. 9 may have a different shape from the planarization layer IPL included in the display device 10. In the following description, the common structures included in the display device 10 as well as the display device 10s may not be described, and the descriptions will focus on differences for economy of explanation.

In some embodiments, the planarization layer IPL included in the display device 10s may cover a first side surface d5 and a second surface d3 of an interlayer dielectric layer ILD.

In some embodiments, the planarization layer IPL included in the display device 10s may include an upper surface p3. The upper surface p3 of the planarization layer IPL may be recessed towards the first conductive layer CDL1 in the third direction DR3 (e.g., in a direction perpendicular to an upper surface of the substrate SUB) and be disposed at a lower height than the first surface d1 of the interlayer dielectric layer ILD. Accordingly, the planarization layer IPL included in the display device 10s may expose a portion of the second side surface d7 of the interlayer dielectric layer ILD.

According to some embodiments, the thickness Tp3 of the planarization layer IPL included in the display device 10s may have a value in a range from about 50% to about 100% of the height differences Hd of the interlayer dielectric layer ILD.

For example, if the thickness Tp3 of the planarization layer IPL has a value less than about 50% of the height differences Hd of the interlayer dielectric layer ILD, the display device 10s may have reliability defects.

According to an embodiment of the present disclosure, the planarization layer IPL may be formed to entirely cover the interlayer dielectric layer ILD and then formed into a shape as shown in FIG. 9 via a subsequent etching process during the process of fabricating the display device 10s.

Referring to FIG. 10 in conjunction with FIGS. 1 to 8, a planarization layer IPL included in a display device 10p of FIG. 10 may have a different shape from the planarization layer IPL included in the display device 10. In the following description, the common structures included in the display device 10 as well as the display device 10s will not be described, and the descriptions will focus on differences for economy of explanation.

In some embodiments, the planarization layer IPL included in the display device 10p may cover a first side surface d5, a second surface d3 and a second side surface d7 of an interlayer dielectric layer ILD.

In some embodiments, the planarization layer IPL included in the display device 10p may include an upper surface p5. The upper surface p5 of the planarization layer IPL may protrude towards one side in the third direction DR3 (e.g., in a direction perpendicular to an upper surface of the substrate SUB) and have a height that is greater than a height of the first surface d1 of the interlayer dielectric layer ILD.

According to some embodiments, the thickness Tp5 of the planarization layer IPL included in the display device 10p may have a value in a range from about 100% to about 120% of the height differences Hd of the interlayer dielectric layer ILD.

For example, if the thickness Tp5 of the planarization layer IPL has a value greater than 120% of the height differences Hd of the interlayer dielectric layer ILD, the display device 10p may have reliability defects.

According to an embodiment of the present disclosure, the planarization layer IPL may be formed to entirely cover the interlayer dielectric layer ILD and then formed into a shape as shown in FIG. 10 via a subsequent etching process during the process of fabricating the display device 10p.

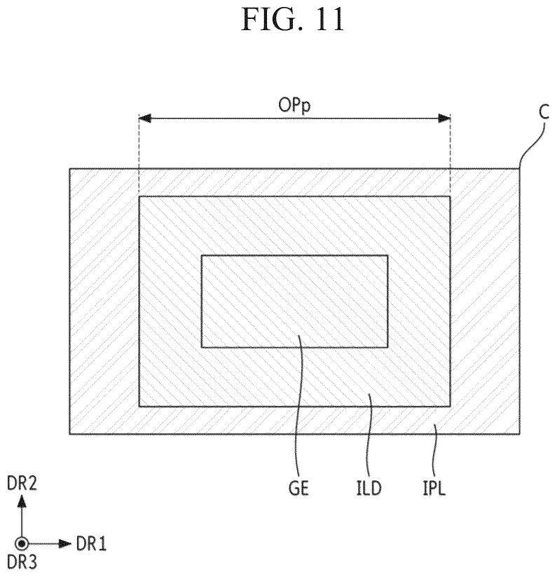

FIG. 11 is a plan view of area C of FIG. 7.

In the plan view of FIG. 11, the planarization layer IPL may define an opening OPp and expose the interlayer dielectric layer ILD in the opening OPp. For example, when viewed from the top, the planarization layer IPL may be in the form of a single pattern completely surrounding the opening OPp.

When viewed from the top, the interlayer dielectric layer ILD and the gate electrode GE may be positioned in the opening OPp. When viewed from the top, the interlayer dielectric layer ILD may entirely cover the gate electrode GE.

When viewed from the top, the planarization layer IPL may not overlap with the gate electrode GE and may completely surround the gate electrode GE. When viewed from the top, the planarization layer IPL may be spaced apart from the gate electrode GE. When viewed from the top, the interlayer dielectric layer ILD may be disposed between the gate electrode GE and the planarization layer IPL spaced apart from each other. In an embodiment, when viewed from the top the planarization layer IPL may completely surround the first conductive layer CDL1, such as the pattern of separated conductive islands which may include the gate electrode GE, the first conductive layer CDL1 and the second conductive layer CDL2.

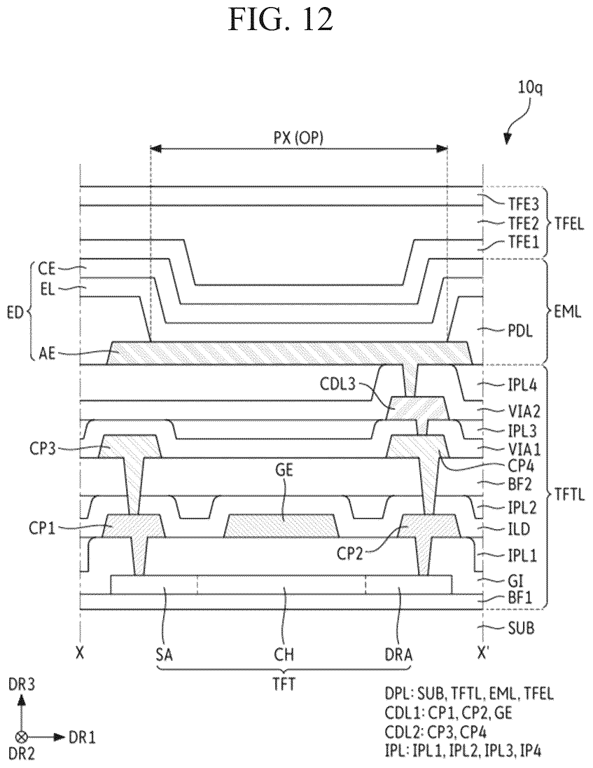

FIG. 12 is a cross-sectional view showing an embodiment of the display layer taken along line X-X′ of FIG. 6.

Referring to FIG. 12 in conjunction with FIGS. 1 to 11, in an embodiment a display layer DPL of a display device 10q may include a substrate SUB, a transistor layer TFTL, a display element layer EML, and a thin-film encapsulation layer TFEL. The transistor layer TFTL included in the display device 10q may include a plurality of planarization layers stacked on one another in the third direction DR3. In the following description, the common structures included in the display device 10q as well as the display device 10 will not be described, and the descriptions will focus on differences for economy of explanation.

The transistor layer TFTL may be disposed on the substrate SUB (e.g., disposed directly thereon in the third direction DR3). In an embodiment, the transistor layer TFTL included in the display device 10q may include a first buffer layer BF1, a transistor TFT, a gate insulator GI, a first planarization layer IPL1, a first conductive layer CDL1, an interlayer dielectric layer ILD, a second planarization layer IPL2, a second buffer layer BF2, a second conductive layer CDL2, a first via layer VIA1, a third planarization layer IPL3, a third conductive layer CDL3, a second via layer VIA2, and a fourth planarization layer IPL4.

The gate insulator GI may be disposed on (e.g., disposed directly thereon) the transistor TFT. The gate insulator GI may cover the height difference formed by the transistor TFT and the first buffer layer BF1 with a uniform thickness. Accordingly, the gate insulator GI may include height differences.

The first planarization layer IPL1 may be disposed on the gate insulator GI (e.g., disposed directly thereon in the third direction DR3). The first planarization layer IPL1 may provide a flat surface over the gate insulator GI. The first planarization layer IPL1 may define an opening, and the first planarization layer IPL1 may expose the gate insulator GI in the opening. For example, the first planarization layer IPL1 may surround the gate insulator GI (e.g., in a plan view).

The first planarization layer IPL1 may include an inorganic insulating material. For example, in an embodiment the first planarization layer IPL1 may include silicon nitride (e.g., Si3N4 or SiNx), silicon oxide (e.g., SiO2 or SiOx), silicon oxynitride (e.g., SiON), titanium oxide, aluminum oxide, or other inorganic insulating materials.

The second planarization layer IPL2 may be disposed on (e.g., disposed directly thereon) the interlayer dielectric layer ILD. The second planarization layer IPL2 may provide a flat surface over the interlayer dielectric layer ILD. The second planarization layer IPL2 may have the same structure and features as the planarization layer IPL included in the display device 10. The redundant descriptions will be omitted for economy of explanation.

The third conductive portion CP3 and the fourth conductive portion CP4 included in the second conductive layer CDL2 may be a conductive pattern including a conductive material. The above-described conductive pattern may refer to a pattern of separated conductive islands.

The third conductive portion CP3 and the fourth conductive portion CP4 included in the second conductive layer CDL2 may be located on the same line in the first direction DR1. For example, the third conductive portion CP3 and the fourth conductive portion CP4 may have a same height from a top surface of the substrate SUB (e.g., in the third direction DR3). The third conductive portion CP3 and the fourth conductive portion CP4 may be spaced apart from each other (e.g., in the first direction DR1). For example, a plurality of conductive patterns may be located on the second buffer layer BF2, and the conductive patterns may be spaced apart from each other in the first direction DR1.

The first via layer VIA1 may be located on (e.g., disposed directly thereon in the third direction DR3) the second buffer layer BF2 and may entirely cover the third conductive portion CP3 and the fourth conductive portion CP4 included in the second conductive layer CDL2. The first via layer VIA1 may cover along the height differences formed by the second conductive layer CDL2 and the second buffer layer BF2 with a uniform thickness. Accordingly, the first via layer VIA1 may include height differences.

The third planarization layer IPL3 may be disposed on (e.g., disposed directly thereon) the first via layer VIA1. The third planarization layer IPL3 may provide a flat surface over the first via layer VIA1. The third planarization layer IPL3 may define an opening, and the third planarization layer IPL3 may expose the first via layer VIA1 in the opening. For example, the third planarization layer IPL3 may surround the first via layer VIA1 (e.g., in a plan view).

The third planarization layer IPL3 may include an inorganic insulating material. For example, in an embodiment the third planarization layer IPL3 may include silicon nitride (e.g., Si3N4 or SiNx), silicon oxide (e.g., SiO2 or SiOx), silicon oxynitride (e.g., SiON), titanium oxide, aluminum oxide, or other inorganic insulating materials.

The third conductive layer CDL3 may be a conductive pattern containing a conductive material. The above-described conductive pattern may refer to a pattern of separated conductive islands.

The second via layer VIA2 may be disposed on (e.g., disposed directly thereon) the first via layer VIA1 and may cover the third conductive layer CDL3. The second via layer VIA2 may cover along the height differences formed by the third conductive layer CDL3 and the first via layer VIA1 with a uniform thickness. Accordingly, the second via layer VIA2 may include height differences.

The fourth planarization layer IPL4 may be disposed on (e.g., disposed directly thereon) the second via layer VIA2. The fourth planarization layer IPL4 may provide a flat surface over the second via layer VIA2. The fourth planarization layer IPL4 may define an opening, and the fourth planarization layer IPL4 may expose the second via layer VIA2 in the opening. For example, the fourth planarization layer IPL4 may surround the second via layer VIA2 (e.g., in a plan view).

The fourth planarization layer IPL4 may include an inorganic insulating material. For example, in an embodiment the fourth planarization layer IPL4 may include silicon nitride (e.g., Si3N4 or SiNx), silicon oxide (e.g., SiO2 or SiOx), silicon oxynitride (e.g., SiON), titanium oxide, aluminum oxide, or other inorganic insulating materials.

The display element layer EML and the thin-film encapsulation layer TFEL included in the display device 10q may be identical to the display element layer EML and the thin-film encapsulation layer TFEL included in the display device 10; and, therefore, the redundant descriptions will be omitted for economy of explanation.

The display device 10q includes a plurality of planarization layers IPL that can provide a flat surface over the height differences formed by a plurality of conductive patterns, thereby reducing reliability defects in the display device 10q caused by the height differences.

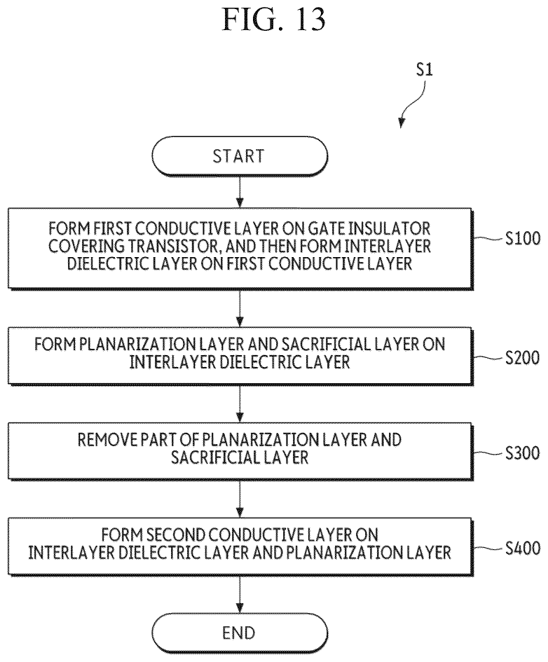

FIG. 13 is a flowchart for illustrating a method for fabricating the transistor layer in FIG. 7.

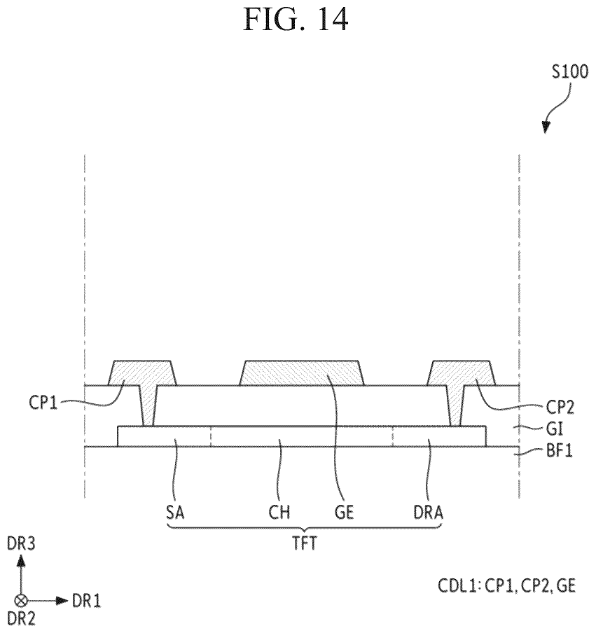

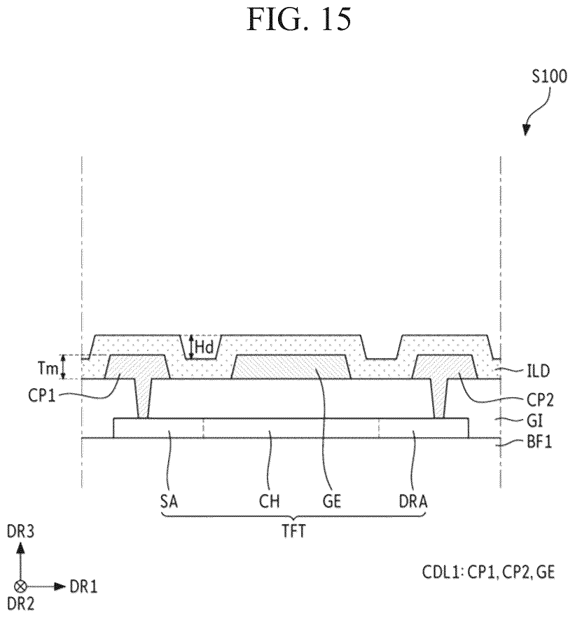

Referring to FIG. 13, a method for fabricating a display device 10 (step S1) according to an embodiment may include: forming a first conductive layer on a gate insulator covering a transistor, and then forming an interlayer dielectric layer on the first conductive layer (step S100); forming a planarization layer and a sacrificial layer on the interlayer dielectric layer (step S200); removing a part of the planarization layer and the sacrificial layer (step S300); and forming a second conductive layer on the interlayer dielectric layer and the planarization layer (step S400). FIGS. 14 and 15 are cross-sectional views showing step S100 of FIG. 13.

Referring to FIGS. 14 and 15, step S100 which includes forming the first conductive layer on the gate insulator covering the transistor and then forming the interlayer dielectric layer on the first conductive layer will be described.

Initially, the transistor TFT is formed on the first buffer layer BFI (e.g., formed directly thereon in the third direction DR3). In an embodiment, the transistor TFT may be formed via a sputtering deposition process. The transistor TFT may be divided into a plurality of regions having different characteristics from each other. For example, the transistor TFT may include a source region SA, a channel region CH, and a drain region DRA. The source region SA and the drain region DRA may be conductive regions compared to the channel region CH.

Subsequently, a gate insulator GI is formed on (e.g., formed directly thereon) the transistor TFT. The gate insulator GI may entirely cover the transistor TFT. For example, the gate insulator GI may entirely cover an upper surface and lateral edges of the transistor TFT.

In an embodiment, the gate insulator GI may be formed via a process of forming an insulating film using at least one of the above-listed insulating materials (e.g., an inorganic insulating material). The material and/or method for forming the gate insulator GI may vary depending on embodiments.

Subsequently, the first conductive layer CDL1 may be formed on the gate insulator GI (e.g., formed directly thereon in the third direction DR3). In an embodiment, the first conductive layer CDL1 may include a gate electrode GE, a first conductive portion CP1 and a second conductive portion CP2. However, embodiments of the present disclosure are not necessarily limited thereto and the number of the separated conductive islands formed in the conductive layers, such as the first conductive layer CDL1, may vary.

In this process, the gate electrode GE may be formed such that it overlaps with the channel region CH of the transistor TFT in the third direction DR3. In an embodiment, the first conductive portion CP1 may be formed such that it overlaps with the source region SA of the transistor TFT (e.g., in the third direction DR3), and the second conductive portion CP2 may be formed such that it overlaps with the drain region DRA of the transistor TFT (e.g., in the third direction DR3).

In an embodiment, the first conductive layer CDL1 may be formed via a film formation process of a conductive film (e.g., a deposition process) and a patterning process of the conductive film (e.g., an etching process using a mask). The material and/or method for forming the first conductive layer CDL1 may vary depending on embodiments. Accordingly, the first conductive layer CDL1 may be formed as a pattern of conductive islands.

In an embodiment, an interlayer dielectric layer ILD is then formed on (e.g., formed directly thereon) the first conductive layer CDL1. The interlayer dielectric layer ILD may be formed on the entire surface, such as on entireties of the top surface and lateral edges of the first conductive layer CDL1.

In this process, the interlayer dielectric layer ILD may cover along the height differences formed between the first conductive layer CDL1 and the gate insulator GI with a uniform thickness. Accordingly, the interlayer dielectric layer ILD may include the height differences Hd. The height differences Hd have been described above and thus will not be described again for economy of explanation.

In this process, the height difference Hd of the interlayer dielectric layer ILD may be less than or equal to the thickness Tm of the first conductive layer CDL1.

In an embodiment, the interlayer dielectric layer ILD may be formed via a deposition process of forming a film using at least one of the above-listed insulating materials (e.g., an inorganic insulating material). However, the material and/or method for forming the interlayer dielectric film ILD may vary depending on embodiments.

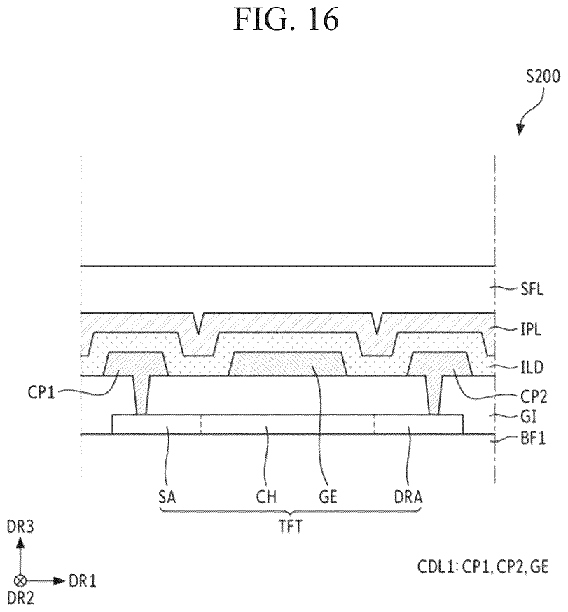

FIG. 16 is a cross-sectional view showing step S200 of FIG. 13.

Referring to FIG. 16, step S200 of forming a planarization layer and a sacrificial layer on an interlayer dielectric layer will be described.

Initially, the planarization layer IPL is formed on (e.g., formed directly thereon) the interlayer dielectric layer ILD. The planarization layer IPL may entirely cover the interlayer dielectric layer ILD, such as entireties of upper surfaces and lateral side surfaces of the interlayer dielectric layer ILD.

In this process, the planarization layer IPL may be formed with a uniform thickness along the height difference Hd of the interlayer dielectric layer ILD. Accordingly, the planarization layer IPL may include height differences.

In an embodiment, the planarization layer IPL may be formed via a deposition process of forming a film of at least one of the above-listed insulating materials (e.g., an inorganic insulating material). The material and/or method for forming the planarization layer IPL may vary depending on embodiments.

In an embodiment, the sacrificial layer SFL is then formed on (e.g., formed directly thereon) the planarization layer IPL. The sacrificial layer SFL may entirely cover the planarization layer IPL. In this process, the sacrificial layer SFL may provide a flat surface over the planarization layer IPL.

In an embodiment, the sacrificial layer SFL may include an organic material, and may include, for example, polyimide, polyamide, phenol, acrylic, epoxy, and silicone. In an embodiment the sacrificial layer SFL may include any material used in organic photoresist (PR) in addition to the above-listed materials.

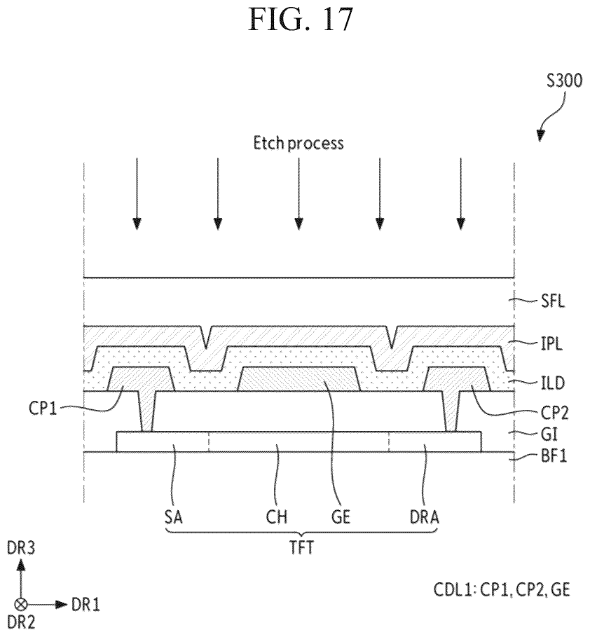

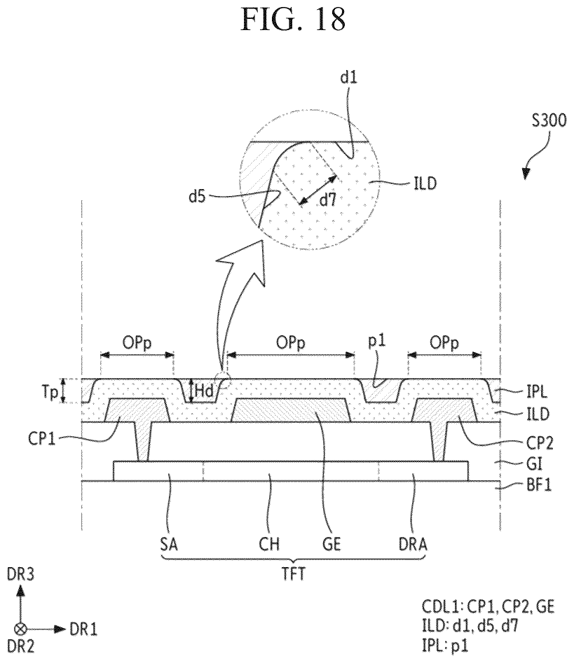

FIGS. 17 and 18 are cross-sectional views showing step S300 of FIG. 13.

Referring to FIGS. 17 and 18, a step of removing a part of the planarization layer and the sacrificial layer (step S300) will be described.

Initially, an etch process is performed on the sacrificial layer SFL.

In an embodiment, the etch process may be performed using an ashing process and/or an etch-back process. Accordingly, this process may be performed without any mask.

For example, in an embodiment an ashing process may be first performed to remove the sacrificial layer SFL. This process may be performed using a plasma containing oxygen or oxygen ions. In this process, the sacrificial layer SFL containing an organic material can be mostly removed without damaging the planarization layer IPL.

Subsequently, an etch-back process is performed when a part of the planarization layer IPL is exposed. This process may control an etch selectivity between the sacrificial layer SFL and the planarization layer IPL. Accordingly, in this process, the sacrificial layer SFL may be completely removed, while the planarization layer IPL may be partially removed to provide a flat surface over the interlayer dielectric layer ILD having the height difference Hd. In an embodiment, the step S300 of removing a part of the planarization layer IPL and the sacrificial layer SFL may be repeated twice or more in whole or in part, as desired.

In this process, the planarization layer IPL may define an opening OPp and expose the interlayer dielectric layer ILD in the opening OPp.

In this process, a part of the interlayer dielectric layer ILD in direct contact with the planarization layer IPL may be removed by an etch-back process. Accordingly, the interlayer dielectric layer ILD may include a second side surface d7 connecting the first surface d1 with the first side surface d5. As described above, the second side surface d7 may be a curved surface. For example, the second side surface d7 of the interlayer dielectric layer ILD may mean that the planarization layer IPL is formed by performing an etch-back process in the process of fabricating the display device 10.

Referring to FIG. 18 in conjunction with FIGS. 8 to 10, in this process, the upper surface p1 of the planarization layer IPL may be located on the same line as the first surface d1 of the interlayer dielectric layer ILD, may protrude towards one side in the third direction DR3 from the first surface d1, or may be recessed toward the opposite side in the third direction DR3 from the first surface d1. The redundant descriptions will be omitted for economy of explanation.

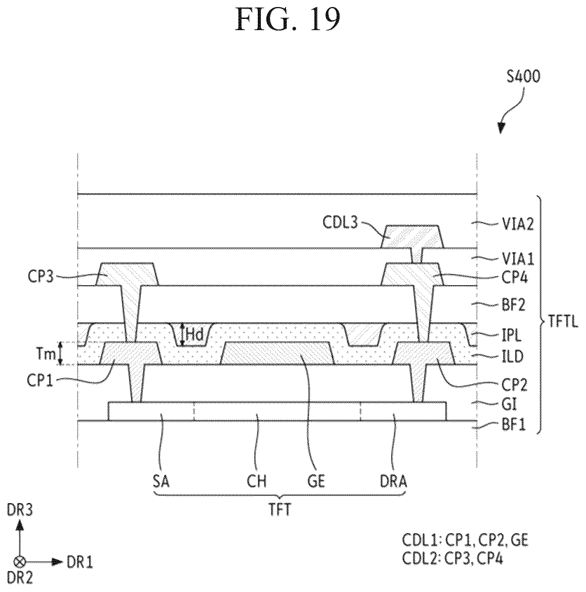

In an embodiment, the thickness Tp of the planarization layer IPL may have a value in a range from about 50% to about 150% of the height differences Hd of the interlayer dielectric layer ILD. The redundant descriptions will be omitted for economy of explanation. FIG. 19 is a cross-sectional view showing step S400 of FIG. 13.

Referring to FIG. 19, step of forming a second conductive layer on the interlayer dielectric layer and the planarization layer (step S400) will be described.

Initially, a second buffer layer BF2 is formed on (e.g., formed directly thereon) the interlayer dielectric layer ILD and the planarization layer IPL. The second buffer layer BF2 may be in direct contact with the interlayer dielectric layer ILD and the planarization layer IPL. In this process, the second buffer layer BF2 is located on the planarization layer IPL, and thus may have a substantially flat film. However, embodiments of the present disclosure are not necessarily limited thereto. For example, in some implementations, the display device 10 may not include a second buffer layer BF2.

In an embodiment, the second buffer layer BF2 may be formed via a deposition process of forming a film of at least one of the above-listed insulating materials (e.g., an inorganic insulating material). The material and/or method for forming the second buffer layer BF2 may vary depending on embodiments.

In an embodiment, a second conductive layer CDL2 is then formed on the second buffer layer BF2. In an embodiment, the second conductive layer CDL2 may include a third conductive portion CP3 and a fourth conductive portion CP4.

In an embodiment, the third conductive portion CP3 may be connected to the first conductive portion CP1 through a contact hole, and the fourth conductive portion CP4 may be connected to the second conductive portion CP2 through a contact hole.

In an embodiment, the second conductive layer CDL2 may be formed via a film formation process of a conductive film (e.g., a deposition process) and a patterning process of the conductive film (e.g., an etching process using a mask). However, the material and/or method for forming the second conductive layer CDL2 may vary depending on embodiments. Accordingly, the third conductive portion CP3 and the fourth conductive portion CP4 included in the second conductive layer CDL2 may be formed as a pattern of conductive islands.

In an embodiment, a first via layer VIA1 covering the second conductive layer CDL2 may then be formed. In this process, the first via layer VIA1 may provide a flat surface over the height differences formed between the second conductive layer CDL2 and the second buffer layer BF2.

In an embodiment, the first via layer VIA1 may be formed via a process of applying at least one of the above-listed organic materials. However, the material and/or method for forming the first via layer VIA1 may vary depending on embodiments.

In an embodiment, a third conductive layer CDL3 may then be formed on the first via layer VIA1. The third conductive layer CDL3 may be connected to the fourth conductive portion CP4 through a contact hole.

In an embodiment, the third conductive layer CDL3 may be formed via a film formation process of a conductive film (e.g., a deposition process) and a patterning process of the conductive film (e.g., an etching process using a mask). However, the material and/or method for forming the third conductive layer CDL3 may vary depending on embodiments. Accordingly, the third conductive layer CDL3 may be formed as a pattern of conductive islands.

In an embodiment, a second via layer VIA2 covering the third conductive layer CDL3 may then be formed. In this process, the second via layer VIA2 may provide a flat surface over the height differences formed between the third conductive layer CDL3 and the second via layer VIA2.

In an embodiment, the second via layer VIA2 may be formed via a process of applying at least one of the above-listed organic materials. However, the material and/or method for forming the second via layer VIA2 may vary depending on embodiments.

In this manner, the transistor layer TFTL shown in FIG. 7 can be formed.

Referring back to FIGS. 1 to 19, the display device 10 according to an embodiment of the present disclosure includes the planarization layer IPL that provides a flat surface over an inorganic insulating layer covering the plurality of conductive patterns, thereby reducing reliability defects of the display device 10.

In addition, in the display device 10 according to an embodiment of the present disclosure, the planarization layer IPL is partially removed via an etching process, and thus no mechanical polishing process (e.g., a CMP process) is required. As a result, the fabrication cost of the display device 10 can be saved.

In addition, in the display device 10 according to an embodiment of the present disclosure, the planarization layer IPL is partially removed via an etch-back process, and thus no mask is required. Therefore, it is possible to more easily fabricate the display device 10.

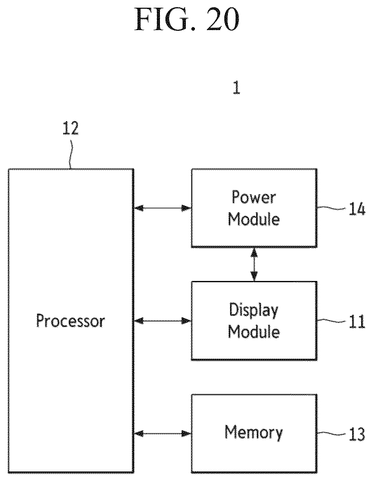

FIG. 20 is a block diagram of an electronic device according to an embodiment of the present disclosure.

Referring to FIG. 20 in conjunction with FIGS. 1 to 19, the display device 10 according to an embodiment may be applied to a variety of electronic devices 1. The electronic device 1 according to an embodiment may include the above-described display device 10, and may further include a module or device having additional functions in addition to the display device 10.

The electronic device 1 according to an embodiment may include a display module 11, a processor 12, a memory 13, and a power module 14.

In an embodiment, the processor 12 may include at least one of: a central processing unit (CPU), an application processor (AP), a graphic processing unit (GPU), a communication processor (CP), an image signal processor (ISP), and a controller.

The memory 13 may store data information required for the operation of the processor 12 or the display module 11. When the processor 12 executes an application stored in the memory 13, an image data signal and/or an input control signal may be transmitted to the display module 11. The display module 11 may process the received signal and output image information through a display screen.

In an embodiment, the power module 14 may include a power supply module such as a power adapter and a battery device, and a power conversion module that converts the power supplied by the power supply module to generate power required for the operation of the electronic device 1.

At least one of the elements of the electronic device 1 described above may be included in the display devices according to embodiments described above. In addition, some of the individual modules functionally included in a single module may be included in a display device, and some others may be provided separately from the display device. For example, in an embodiment the display device may include the display module 11, and the processor 12, the memory 13 and the power module 14 may be implemented as other devices inside the electronic device 1 instead of the display device.

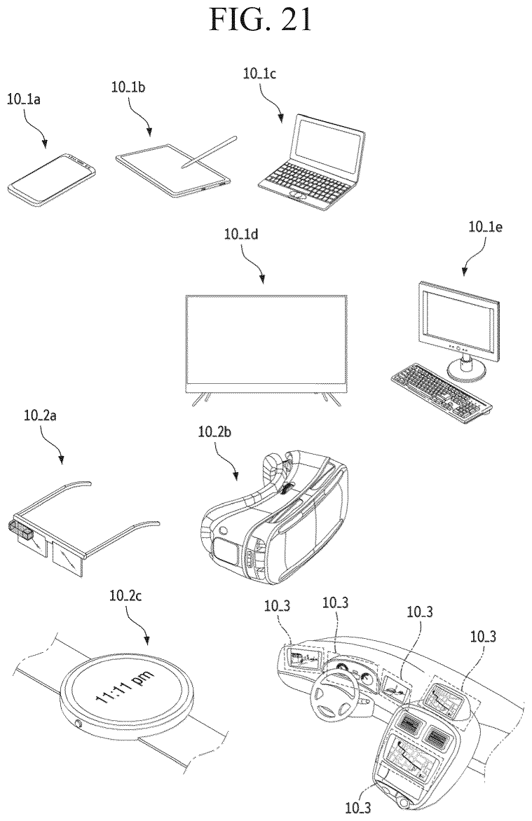

FIG. 21 is a view showing electronic devices according to a variety of embodiments of the present disclosure.

Referring to FIG. 21, a variety of electronic devices 1 having the display devices 10 applied thereto according to embodiments may include not only image display electronic devices such as a smart phone 1_1a, a tablet PC 1_1b, a laptop computer 1_1c, a TV 1_1d and a desktop monitor 1_1e, but also wearable electronic devices including display modules such as smart glasses 1_2a, a head-mounted display 1_2b and a smart watch 1_2c, and electronic devices for vehicles 1_3 including display modules such as a center information display (CID) placed on the dashboard, the center fascia and the dashboard of a vehicle, and a room mirror display.

It should be understood that embodiments described herein should be considered in a descriptive sense and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope of the present disclosure.

What is claimed is:

1. A display device comprising:
a substrate having a transistor disposed thereon;
a gate insulator disposed on the transistor;
a plurality of conductive layers disposed on the gate insulator, the plurality of conductive layers is spaced apart from one another;
an interlayer dielectric layer disposed on the plurality of conductive layers, the interlayer dielectric layer comprising an inorganic material; and
a planarization layer disposed on the interlayer dielectric layer and defining an opening, the opening exposing the interlayer dielectric layer,
wherein the planarization layer comprises an inorganic material.

2. The display device of claim 1, wherein each of the plurality of conductive layers overlaps the opening of the planarization layer.

3. The display device of claim 2, wherein the planarization layer is disposed between adjacent conductive layers of the plurality of conductive layers in a plan view.

4. The display device of claim 3, wherein:
the plurality of conductive layers comprise a conductive metal; and
the plurality of conductive layers are disposed on a same layer as each other and overlap each other in a direction parallel to an upper surface of the substrate.

5. The display device of claim 4, wherein the plurality of conductive layers has an island-like shape.

6. The display device of claim 1, wherein:
the interlayer dielectric layer is disposed on an entirety of the substrate; and
the interlayer dielectric layer is in direct contact with an entirety of upper surfaces and lateral side surfaces of the plurality of conductive layers to cover the plurality of conductive layers.
wherein the interlayer dielectric layer has a height difference between portions that do not overlap with the opening and portions that overlap with the opening.
wherein a thickness of the planarization layer is in a range from about 50% to about 150% of the height difference of the interlayer dielectric layer.

7. The display device of claim 1, wherein:
the interlayer dielectric layer comprises a first surface disposed in the opening and is located on an opposite side of a surface of the interlayer dielectric layer directly contacting the plurality of conductive layers; and
the planarization layer comprises an upper surface having a height greater than the plurality of conductive layers.

8. The display device of claim 7, wherein the upper surface of the planarization layer is located on a same line as the first surface of the interlayer dielectric layer.

9. The display device of claim 7, wherein the upper surface of the planarization layer is recessed in a direction perpendicular to an upper surface of the substrate more than the first surface of the interlayer dielectric layer.

10. The display device of claim 7, wherein the upper surface of the planarization layer protrudes in a direction perpendicular to an upper surface of the substrate more than the first surface of the interlayer dielectric layer.

11. The display device of claim 1, wherein the planarization layer is arranged as a pattern completely surrounding the opening in a plan view. wherein:
the plurality of conductive layers is located in the opening in the plan view;
the plurality of conductive layers and the planarization layer are spaced apart from each other in the plan view; and
the planarization layer completely surrounds the plurality of conductive layers in the plan view,
wherein:
the interlayer dielectric layer entirely covers the plurality of conductive layers in the opening in the plan view; and
the interlayer dielectric layer is located between the planarization layer and the plurality of conductive layers.

12. A method for fabricating a display device, the method comprising:
forming conductive layers on a gate insulator covering a transistor, and then forming an interlayer dielectric layer on the conductive layers;
forming a planarization layer and a sacrificial layer on the interlayer dielectric layer; and
removing a portion of the planarization layer and the sacrificial layer,
wherein the removing the portion of the planarization layer and the sacrificial layer comprises removing the portion of the planarization layer and the sacrificial layer via an etching process comprising an etch-back process.

13. The method of claim 12, wherein the forming of the interlayer dielectric layer on the conductive layers comprises: forming the interlayer dielectric layer so that the interlayer dielectric layer covers the conductive layers entirely and the interlayer dielectric layer has a uniform thickness with a fabrication error less than or equal to about 10%.

14. The method of claim 12, wherein:
the planarization layer comprises an inorganic material; and
the sacrificial layer comprises an organic material.

15. The method of claim 14, wherein the planarization layer defines an opening, and the planarization layer exposes the interlayer dielectric layer in the opening.

16. An electronic device comprising:
at least one display device comprising a substrate having a transistor disposed thereon;
a display device housing accommodating the at least one display device; and
an optical member magnifying a display image of the at least one display device or converting a light path,
wherein the at least one display device comprises:
a gate insulator disposed on the transistor;
a plurality of conductive layers disposed on the gate insulator, the plurality of conductive layers is spaced apart from one another;
an interlayer dielectric layer disposed on the plurality of conductive layers, the interlayer dielectric layer comprising an inorganic material; and
a planarization layer disposed on the interlayer dielectric layer and defining an opening, the opening exposing the interlayer dielectric layer;
wherein the planarization layer comprises an inorganic material.

17. The electronic device of claim 16, wherein each of the plurality of conductive layers overlaps the opening of the planarization layer.

18. The electronic device of claim 17, wherein the planarization layer is disposed between adjacent conductive layers of the plurality of conductive layers in a plan view.

19. The electronic device of claim 18, wherein:
the plurality of conductive layers comprise a conductive metal; and
the plurality of conductive layers are disposed on a same layer as each other and overlap each other in a direction parallel to an upper surface of the substrate.

20. The electronic device of claim 19. wherein the plurality of conductive layers has an island-like shape.
